(19) United States
(12) Patent Application Publication
(10) Pub. No.: US 2020/0310245 A1
(43) Pub. Date: Oct. 1, 2020

(54) MASK REPAIR APPARATUS AND METHOD FOR REPAIRING MASK

(71) Applicant: HITACHI HIGH-TECH SCIENCE CORPORATION, Tokyo (JP)

(72) Inventors: Tomokazu KOZAKAI, Tokyo (JP); Fumio ARAMAKI, Tokyo (JP); Osamu MATSUDA, Tokyo (JP); Kensuke SHIINA, Tokyo (JP)

(21) Appl. No.: 16/817,249

(22) Filed: Mar. 12, 2020

(30) Foreign Application Priority Data
Mar. 25, 2019 (JP) 2019-057370

(51) Int. Cl. G03F 1/72; G03F 1/22; G03F 7/20

(52) U.S. Cl. CPC G03F 1/72; G03F 7/70783; G03F 1/22

(57) ABSTRACT

The present disclosure relates to a mask repair apparatus capable of efficiently repairing a defect of a target EUVL mask. The mask repair apparatus repairs the defect of the target extreme ultra violet lithography (EUVL) mask having a reflective layer, a first layer disposed on the reflective layer, and a second layer disposed on the first layer, and a third layer disposed on the second layer. The mask repair apparatus performs etching of the third layer by a first etching method, and after the etching of the third layer by the first etching method, performs etching of the second layer by the second etching method different from the first etching method.

### CROSS REFERENCE TO RELATED APPLICATION(S)

This application claims the benefit of Japan Patent Application No. 2019-057370, filed on Mar. 25, 2019, which is hereby incorporated by reference in its entirety into this application.

### BACKGROUND OF THE INVENTION

### 1. Technical Field

The present disclosure relates generally to a mask repair apparatus and a method for repairing a mask.

### 2. Description of the Related Art

A mask repair apparatus for repairing a defect of an extreme ultra violet lithography (EUVL) mask by using a charged particle beam has been researched and developed.

EUVL is lithography using extreme ultra violet (EUV) as a light source. That is, the EUVL mask is a photomask used in EUVL. The EUVL mask consists of a reflective layer having an ultrathin multilayer structure, and an absorption layer having a pattern shape. In the description, the defect of the EUVL mask means a defect of the pattern shape of the absorption layer of the EUVL mask. The mask repair apparatus repairing a defect of the EUVL mask irradiates the defect with the charged particle beam to repair the defect by etching processing or deposition processing (referring to Patent Document 1).

### Documents of Related Art

(Patent Document 1) Japan Patent Application Publication No. 2015-064603

### SUMMARY OF THE INVENTION

Recently, a EUVL mask in which a new layer is overlaid on an absorption layer has been developed. The EUVL mask, for example, may have high cleaning resistance with respect to the absorption layer and may prevent unintentional scratches on the absorption layer. In the description, the new layer is referred to as an additional layer. Further, the EUVL mask with the additional layer overlaid on the absorption layer is referred to as a target EUVL mask.

It may be difficult to etch the additional layer of the target EUVL mask by the same method as a method of processing the absorption layer. For example, etching gas used for etching of absorption layer in gas assist etching (GAE) may have a multiplication nature with respect to a material of the absorption layer, but may have no multiplication nature with respect to a material of the additional layer. In this case, the etching gas may perform the etching of the absorption layer, but may not perform the etching of the additional layer. As a result, the mask repair apparatus may not efficiently repair the defect of the target EUVL mask.

Accordingly, the present disclosure has been made keeping in mind at least one of the above problem in the related art, and the present disclosure is intended to propose a mask repair apparatus capable of efficiently repairing the defect of the target EUVL mask and a method for repairing a mask.

In an embodiment of the present disclosure, a mask repair apparatus repairs a defect of the target EUVL mask comprising a reflective layer, a first layer disposed on the reflective layer, and a second layer disposed on the first layer, and a third layer disposed on the second layer, wherein the mask repair apparatus may be configured to perform etching of the third layer by a first etching method, and then to perform etching of the second layer by a second etching method that is different from the first etching method after the third layer is etched by the first etching method.

Further, in another embodiment of the present disclosure, a method for repairing a mask, the method being used to repair a target EUVL mask having a reflective layer, a first layer disposed on the reflective layer, and a second layer disposed on the first layer, and a third layer disposed on the second layer, may include: etching of the third layer by a first etching method; and etching of the second layer by a second etching method that is different from the first etching method after the etching of the third layer by the first etching method.

As described above, the present disclosure proposes a mask repair apparatus that can efficiently repair a defect of the target EUVL mask and a method for repairing a mask.

### BRIEF DESCRIPTION OF THE DRAWINGS

The above and other objects, features, and advantages of the present disclosure will be more clearly understood from the following detailed description taken in conjunction with the accompanying drawings, in which:

FIG. 1 is a view illustrating an example of a configuration of a mask repair apparatus 100 according to a first embodiment;

FIG. 2 is a view illustrating an example of a configuration of an ion source 12;

FIG. 3 is a sectional view illustrating an example of a section of a target EUVL mask, when the target EUVL mask is cut along a surface perpendicular to an upper surface of the target EUVL mask;

FIG. 4 is a block diagram illustrating an example of a functional configuration of a control device 10;

FIG. 5 is a flowchart illustrating an example of processing for repairing a defect of the target EUVL mask by the mask repair apparatus 100; and

FIG. 6 is a flowchart illustrating another example of processing for repairing the defect of the target EUVL mask by the mask repair apparatus 100.

### DESCRIPTION OF THE PREFERRED EMBODIMENTS

### <1^{ST} Embodiment>

Hereinbelow, a first embodiment of the present disclosure will be described in detail below with reference to the accompanying drawings.

### <Configuration of Mask Repair Apparatus>

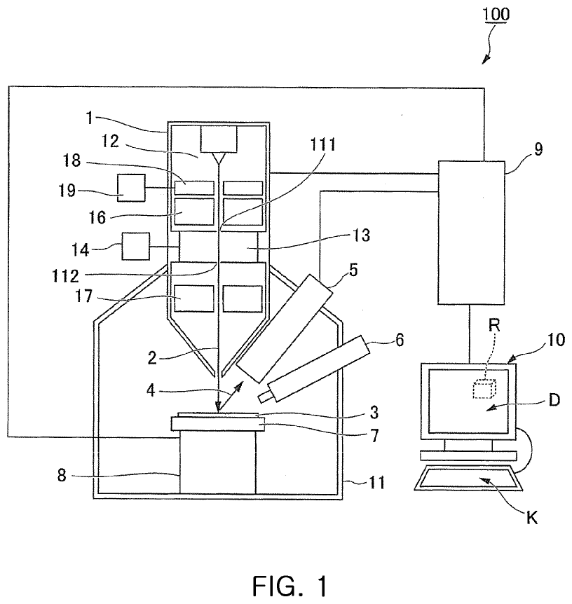

First, a configuration of the mask repair apparatus 100 of the first embodiment will be described. FIG. 1 is a view illustrating an example of a configuration of a mask repair apparatus 100 according to the first embodiment.

The mask repair apparatus 100 is configured to repair a defect of a target extreme ultra violet lithography (EUVL) mask. The target EUVL mask is an EUVL mask that is an object to be repaired by the mask repair apparatus 100. Multiple types of EUVL masks are provided. The mask repair apparatus 100 repairs defects of several types of EUVL masks of the EUVL masks as a defect of the target EUVL mask. The target EUVL mask will be described in detail. Further, the mask repair apparatus 100 may repair the defect of the target EUVL mask, and also repair a defect of another EUVL mask different from the target EUVL mask.

For example, the mask repair apparatus 100 is a focused ion beam apparatus irradiating a target object with a focused ion beam. The mask repair apparatus 100 includes an ion beam column 1, a secondary electron detector 5, a gas supply 6, a sample holder 7, and a sample stage 8.

The ion beam column 1 is provided with an ion-optics. The ion-optics provided in the ion beam column 1 includes a condenser lens electrode 16 and an objective lens electrode 17 that focus an ion generated from an ion source 12 on the sample 3 placed in a vacuum sample chamber 11. As illustrated in FIG. 1, an ion beam 2 is radiated from the ion beam column 1. The secondary electron detector 5 is configured to detect a secondary electron 4 generated by irradiating the sample 3 with an ion beam (for example, the ion beam 2) from the ion beam column 1. The gas supply 6 is configured to supply gas on a surface of the sample 3. The sample holder 7 is configured to fix the sample 3. The sample stage 8 moves the sample 3. Further, the above-described target EUVL mask is an example of the sample 3.

Further, the mask repair apparatus 100 may be provided with a charged particle beam column instead of the ion beam column 1. The charged particle beam column is provided with a charged particle optics. The charged particle optics includes the condenser lens electrode and the objective lens electrode that focus a charged particle that is different from the ion and generated from a charged particle source on the sample 3 placed in the vacuum sample chamber 11. Further, instead of the secondary electron detector 5 or in addition to the secondary electron detector 5, the mask repair apparatus 100 may be provided with a secondary charged particle detector, the secondary charged particle detector detecting a charged particle other than the secondary electron 4 of secondary charged particles generated by irradiating the sample 3 with the ion beam from the ion beam column 1. For example, the mask repair apparatus 100 may be provided with a secondary ion detector as the secondary charged particle detector for detecting a secondary ion generated from the sample 3. Further, the mask repair apparatus 100 may be provided with a back-scattered ion detector as the secondary charged particle detector for detecting a back-scattered ion generated from the sample 3.

Further, the mask repair apparatus 100 may be configured such that the sample holder 7 and the sample stage 8 are integrated into a single body.

Further, the mask repair apparatus 100 includes an image forming portion 9 and a control device 10.

The image forming portion 9 is configured to form an observation image from an scanning signal of the ion beam and a detecting signal of the secondary electron detector 5.

The control device 10 is configured to control the whole mask repair apparatus 100. The control device 10 includes a central processing unit (CPU, not illustrated), a storage R, an input receipt portion K, and a display portion D.

For example, the storage R includes a hard disk drive (HDD), a solid state drive (SSD), an electrically erasable programmable read-only memory (EEPROM), a read-only memory (ROM), a random access memory (RAM), etc. Further, the storage R may be an external storage accessed to the control device 10 by a digital input/output port such as USB instead of being embedded in the control device 10. The storage R storages a variety of information, images, and program that are processed by the control device 10.

For example, the input receipt portion K is an input device such as a keyboard, a mouse, a touch pad, etc. Further, the input receipt portion K may be a touch panel integrated with the display portion D.

The display portion D is a display device, such as a liquid crystal display (LCD) panel and an electro luminescence (EL) display panel. The display portion D, for example, is configured to display the observation image formed by the image forming portion 9.

### <Configuration of Ion Source>

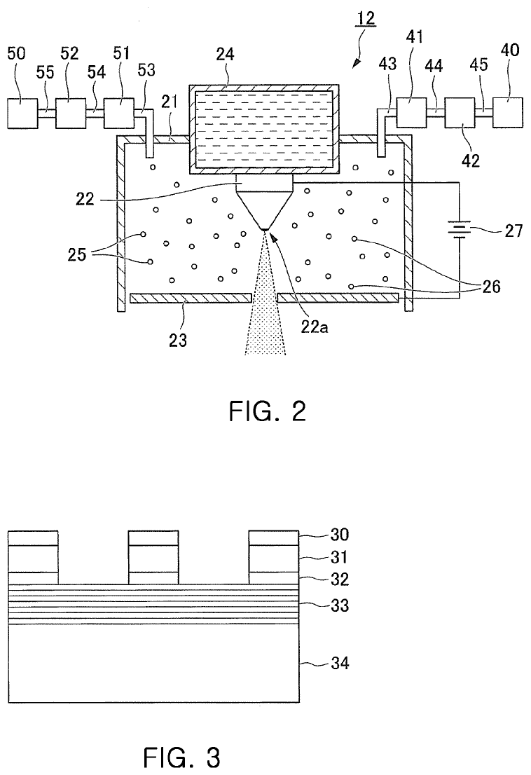

Hereinbelow, a configuration of the ion source 12 will be described with reference to FIG. 2. FIG. 2 is a view illustrating an example of the configuration of the ion source 12.

The ion source 12 is a field ionization type ion source. The ion source 12 includes, for example, an ion source chamber 21, an emitter 22, an extraction electrode 23, and a cooling device 24.

The cooling device 24 is disposed on a wall of the ion source chamber 21. The emitter 22 having a needle shape is mounted on a surface facing the ion source chamber 21 of the cooling device 24. The cooling device 24 is configured to cool the emitter 22 with a refrigerant such as liquid nitrogen and liquid helium stored therein. Further, the ion source 12 may include a closed cycle refrigerator such as a GM type, a pulse tube type, and a gas-flow type refrigerator, as the cooling device 24. The extraction electrode 23 having an opening at a position opposite to a tip 22a of the emitter 22 is disposed near an opening end of the ion source chamber 21.

The inside of the ion source chamber 21 is maintained in a desired high vacuum state by an exhaust device (not illustrated). In the first embodiment, two kinds of gases are supplied into the ion source chamber 21. In detail, the ion source chamber 21 is connected with a nitrogen gas supply source 40 via gas introduction tubes 43, 44, and 45. Thus, a small amount of nitrogen gas is supplied into the ion source chamber 21. Further, the ion source chamber 21 is connected with a hydrogen gas supply source 50 via gas introduction tubes 53, 54, and 55. Thus, a small amount of hydrogen gas is supplied into the ion source chamber 21. A concentration ratio of nitrogen gas and hydrogen gas in the ion source chamber 21 is, for example, nitrogen gas:hydrogen gas=1:1, but is not limited thereto. The concentration ratio is adjusted so that each electric current value of a nitrogen ion beam radiated from the ion beam column 1 and of a hydrogen ion beam radiated from the ion beam column 1 may become a desired electric current value.

The emitter 22 is formed by coating precious metal such as platinum, palladium, iridium, rhodium, and gold on a needle-shaped base material made of tungsten or molybdenum. The tip 22a of the emitter 22 has a pyramidal shape (i.e., quadrangular pyramidal shape) sharpened to the atomic level. Further, a needle-shaped base material made of tungsten or molybdenum that is atomically sharpened like the tip 22a by an introduction of nitrogen gas or hydrogen gas (not illustrated) may be used as the emitter 22. Further, the emitter 22 is maintained at a low temperature of 100 K or less by the cooling device 24 during operation of the ion source 12. A voltage is applied between the emitter 22 and the extraction electrode 23 by a power 27. Hereinafter, for convenience of description, the voltage is referred to as an extraction voltage.

When a first extraction voltage is applied between the emitter 22 and the extraction electrode 23, an electric field is formed at the sharp-pointed tip 22a by the first extraction voltage. A nitrogen molecule 25 polarized by the electric field and attracted to the emitter 22 loses an electron by tunneling at a high position of the electric field in the tip 22a to become a nitrogen ion. As described above, there is difference between the energy required to ionize the nitrogen molecule 25 and the energy required to ionize a hydrogen molecule 26. Therefore, in this case, the hydrogen molecule 26 is also polarized by the electric field and attracted to the emitter 22, but most of the hydrogen molecule 26 in the ion source chamber 21 is not ionized.

In the ion source chamber 21, the generated nitrogen ion is repelled from the emitter 22 maintained in a negative potential toward the extraction electrode 23. Then, the nitrogen ion is emitted from the ion-optics of the ion beam column 1 through the opening of the extraction electrode 23, thereby forms a nitrogen ion beam. The nitrogen ion beam includes a nitrogen molecular ion and a nitrogen atom ion when the ion source 12 is the field ionization type ion source. Further, an abundance ratio between the nitrogen molecular ion and the nitrogen atom ion in the nitrogen ion beam is changed with respect to the first extraction voltage.

Meanwhile, when a second extraction voltage is applied between the emitter 22 and the extraction electrode 23, the electric field is formed at the sharp-pointed tip 22a by the second extraction voltage. The hydrogen molecule 26 polarized by the electric field and attracted to the emitter 22 loses an electron by tunneling at a high position of the electric field in the tip 22a to become a hydrogen ion. As described above, there is difference between the energy required to ionize the nitrogen molecule 25 and the energy required to ionize the hydrogen molecule 26. Therefore, in this case, the nitrogen molecule 25 is also polarized by the electric field and attracted to the emitter 22, but most of the nitrogen molecule 25 in the ion source chamber 21 is not ionized.

In the ion source chamber 21, the generated hydrogen ion is repelled from the emitter 22 maintained in a positive potential toward the extraction electrode 23. Then, the hydrogen ion is emitted from the ion-optics of the ion beam column 1 through the opening of the extraction electrode 23, thereby forms a hydrogen ion beam. The hydrogen ion beam includes a hydrogen molecular ion and a hydrogen atom ion when the ion source 12 is the field ionization type ion source. Further, an abundance ratio between the hydrogen molecular ion and the hydrogen atom ion in the hydrogen ion beam is changed with respect to the second extraction voltage.

Further, the ion beam 2 illustrated in FIG. 1 illustrates an example of the nitrogen ion beam or the hydrogen ion beam.

The tip 22a of the emitter 22 has an extremely sharp shape. Each of the nitrogen ion and the hydrogen ion is bumped from the tip 22a. Thus, an energy distribution width of an ion beam (each of nitrogen ion beam and hydrogen ion beam) emitted from the ion source 12 is extremely narrow. For example, the ion source 12 may emit an ion beam having a high brightness and a small beam diameter compared with a plasma type gas ion source or a liquid metal ion source.

When the hydrogen gas and the nitrogen gas supplied into the ion source chamber 21 contain water molecules, water is absorbed on the emitter 22 and a projection is formed. In this case, the generated ion (i.e., each of nitrogen ion and hydrogen ion) is emitted in a direction different from an optic axis of the ion beam with respect to the tip 22a of the emitter 22. The absorption of water molecules occurs randomly. For this reason, the amount of current of the ion beam emitted from the ion source 12 in a direction of the optic axis may be greatly changed. In order to avoid the absorption, each of the nitrogen gas and the hydrogen gas supplied into the ion source chamber 21 is purified.

Each of the gas introduction tubes 43, 44, and 45 is metal plumbing. As each of the gas introduction tubes 43, 44, and 45, for example, a stainless-electro polished (SUS-EP) tube of which the surface roughness is reduced by electric field polishing may be used. In the ion source 12, each of the gas introduction tubes 43, 44, and 45 is heated in advance to several hundred degrees Celsius to reduce the absorption of water molecules into a surface of each of the gas introduction tubes 43, 44, and 45.

Further, a purifier is provided in the ion source 12 to purify the nitrogen gas supplied from the nitrogen gas supply source 40. A first purifier 41 is configured such that the nitrogen gas is purified by allowing impurity gas to be absorbed into a getter material composed of a plurality of active metals or by allowing the impurity gas to penetrate a heated palladium thin film. A second purifier 42 is configured to remove impurities from the nitrogen gas by a cold trap using liquid nitrogen.

Thus, the nitrogen gas of high purity 9N (99.9999999%) or more is supplied to the ion source 12. The ion source 12 may be provided with any one of the first purifier 41 and the second purifier 42 as the purifier. Further, in the ion source 12, the purifier may be included in the nitrogen gas supply source 40.

Further, a purifier is provided in the ion source 12 to purify the hydrogen gas supplied from the hydrogen gas supply source 50. The first purifier 51 is configured such that the hydrogen gas is purified by allowing impurity gas to be absorbed into the getter material composed of the plurality of active metals or by allowing the hydrogen gas to penetrate the heated palladium thin film. The second purifier 52 is configured to remove impurities from the hydrogen gas by the cold trap using liquid nitrogen.

Thus, the hydrogen gas of high purity 9N (99.9999999%) or more is supplied to the ion source 12. The ion source 12 may be provided with any one of the first purifier 51 and the second purifier 52 as the purifier. Further, in the ion source 12, the purifier may be included in the hydrogen gas supply source 50.

Further, in order to reduce the inflow of impurity gas from the vacuum sample chamber 11 to the ion source chamber 21, an intermediate chamber 13 in a vacuum state is provided in the ion beam column 1. The intermediate chamber 13 is exhausted by an exhaust pump 14 different from the exhaust device for exhausting the ion source chamber 21. The generated ion beam (for example, hydrogen ion beam and nitrogen ion beam) in the ion source chamber 21 passes through a hole of a small-diameter between vacuum chambers and is radiated to the vacuum sample chamber 11. A hole 111 is provided between the ion source chamber 21 and the intermediate chamber 13. A hole 112 is provided between the intermediate chamber 13 and the vacuum sample chamber 11. The ion beam column 1 may be configured such that the intermediate chamber 13 stores the objective lens electrode 17, and a position of the hole 112 is closer to the vacuum sample chamber 11 than the objective lens electrode 17. Accordingly, when base gas or etching gas of a deposition film is used in the vacuum sample chamber 11, it is possible to reduce the impurity gas of the base gas or the etching gas from flowing into the ion source chamber 21.

ps <Configuration of Ion-optics Provided in Ion Beam Column>

Hereinafter, the ion-optics provided in the ion beam column 1 will be described.

The ion-optics includes the condenser lens electrode 16 focusing the ion beam (for example, hydrogen ion beam, nitrogen ion beam, etc.) generated in the ion source chamber 21 and the objective lens electrode 17 focusing the ion beam on the sample 3, in order from the ion source 12 to the vacuum sample chamber 11.

According to the configuration, the ion beam column 1 may have a source size of 1 nm or less and energy spreading of the ion beam of 1 eV and less. As a result, the ion to beam column 1 may narrow a beam diameter to 5 nm and less. Further, the ion beam column 1 may be provided with a mass filter (not illustrated) such as an ExB mass filter for sorting an atomic number of ion.

Further, by the configuration, the ion beam column 1 may adjusts each voltage applied to the condenser lens electrode 16 and to the objective lens electrode 17, so that an irradiation position of the ion beam radiated from the ion beam column 1 may be adjusted.

### <Current Measuring of Ion Beam>

The ion beam column 1 includes a current measuring electrode 18 provided between the ion source 12 and the condenser lens electrode 16. The current measuring electrode 18 is configured to measure the amount of current of the ion beam (for example, hydrogen ion beam, the nitrogen ion beam, etc.). The current measuring electrode 18 is connected with an ammeter 19. The ammeter 19 measures the amount of current of the ion beam radiated to the current measuring electrode 18. The mask repair apparatus 100 controls the extraction electrode 23 of the ion source 12 so that the amount of current measured by the ammeter 19 is constant. Accordingly, the mask repair apparatus 100 may radiate the ion beam having the stable amount of current to the sample 3.

### <Configuration of Gas Supply>

The gas supply 6 supplies the base gas of the deposition film (for example, carbon-based gas such as phenanthrene and naphthalene, metallic compound gas containing platinum or tungsten, etc.) on the surface of the sample 3 through a gas nozzle from a base material container.

Further, the gas supply 6 supplies the etching gas (for example, xenon fluoride, chlorine, iodine, chlorine trifluoride, fluorine monoxide, water, etc.) through the gas nozzle from the base material container, when performing etching process.

### <Configuration of Target EUVL Mask>

Referring to FIG. 3, a configuration of the target EUVL mask will be described. FIG. 3 a sectional view illustrating an example of a section of a target EUVL mask, when the target EUVL mask is cut along a surface perpendicular to an upper surface of the target EUVL mask.

The target EUVL mask used as the sample 3 includes a multilayered reflective layer 33 of Mo/Si on a glass substrate 34, a first layer 32 disposed on the reflective layer 33, a second layer 31 disposed on the first layer 32, and a third layer 30 disposed on the second layer 31, as illustrated in FIG. 3.

The first layer 32 is a cap layer of the target EUVL mask. Hereinafter, as an example, the first layer 32 made of ruthenium (Ru) will be described. Further, a material of the first layer 32 may be another material instead of Ru.

The second layer 31 is an absorption layer of the target EUVL mask. Hereinafter, as an example, the second layer 31 made of tantalum (TaN) will be described. Further, a material of the second layer 31 may be another material instead of TaN.

The third layer 30 is an additional layer. The third layer 30 protects, for example, the second layer 31. A material of the third layer 30 is, for example, aluminum (Al), chromium (Cr), Ru, etc. Further, the material of the third layer 30 may be another material instead thereof. Hereinafter, for example, the third layer 30 made of Al, which will be described later.

In EUVL, extreme ultra violet is radiated to a EUVL mask, and a mask pattern is transferred by using reflected light. When a pattern shape of the absorption layer of a EUVL mask has a defect, since the pattern is transferred together with the defect, defect repairing is necessary. The problem of the EUVL mask also occurs in the target EUVL mask. Accordingly, the mask repair apparatus 100 repairs a defect of the target EUVL mask.

### <Functional Configuration of Controller>

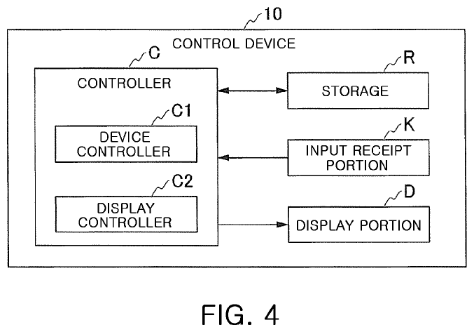

Hereinafter, a functional configuration of the control device 10 will be described with reference to FIG. 4. FIG. 4 is a block diagram illustrating an example of the functional configuration of the control device 10.

The control device 10 includes the storage R, the input receipt portion K, the display portion D, and a controller C.

The controller C controls the whole control device 10. The controller C includes a device controller C1 and a display controller C2. The functional unit included in the controller C is realized such that, for example, the CPU (not illustrated) included in the control device 10 executing various programs stored in the storage R. Further, some or all of the functional unit may be a hardware functional unit such as large scale integration (LSI) or an application specific integrated circuit (ASIC).

The device controller C1 controls the whole mask repair apparatus 100 on the basis of an operation, an operation program, etc. received from a user via the input receipt portion K.

The display controller C2 creates various images displayed in the display portion D. The display controller C2 outputs created images on the display portion D to display the images on the display portion D. For example, the display controller C2 creates an image including the observation image formed by the image forming portion 9, and display the created image on the display portion D.

### <Processing For Repairing Defect of Target EUVL Mask By Mask Repair Apparatus>

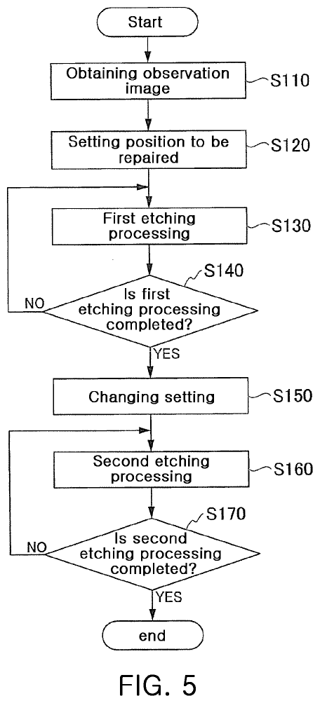

Hereinafter, processing for repairing the defect of the target EUVL mask by the mask repair apparatus 100 will be described with reference to FIG. 5. FIG. 5 is a flowchart illustrating an example of the processing for repairing the defect of the target EUVL mask by the mask repair apparatus 100. Further, in the first embodiment, the defect of the target EUVL mask that is an object to be repaired by the mask repair apparatus 100 is an opaque defect. The opaque defect of defects of the target EUVL mask may be removed by etching processing.

The device controller C1 makes various settings at the timing before processing S110 illustrated in FIG. 5 is performed.

The device controller C1 sets the above-described first extraction voltage to the ion beam column 1 as an extraction voltage applied between the emitter 22 and the extraction electrode 23.

Further, the device controller C1 reads first observation condition information stored in the storage R from the storage R. The device controller C1 sets various observation conditions indicated by the first observation condition information to the ion beam column 1. The first observation condition information indicates various observation conditions when the mask repair apparatus 100 radiates the nitrogen ion beam. The various observation conditions include an acceleration voltage for accelerating the nitrogen ion beam, a beam current of the nitrogen ion beam, a lens mode which is an operation mode of an objective lens focusing the nitrogen ion beam, a type of the sample holder 7 maintaining the sample 3, a material of the sample 3, a position of the sample stage 8 where the sample 3 is placed, etc. Further, the various observation conditions may include another condition, instead of some or all of the conditions or in addition to some or all of the conditions. Further, the acceleration voltage is determined by a thickness of the third layer 30 of the target EUVL mask. For example, when the thickness is about 10 nm, the acceleration voltage is determined so that the energy of the nitrogen ion beam is about 15 keV. Accordingly, the mask repair apparatus 100 performs the etching of the third layer 30 by radiating the nitrogen ion beam without damaging to the reflective layer 33.

Further, the device controller C1 reads first lens parameter information stored in advance in the storage R from the storage R. The device controller C1 sets various parameters indicated by the read first lens parameter information to the ion beam column 1. The first lens parameter information indicates various parameters set to the ion beam column 1 when the mask repair apparatus 100 radiates the nitrogen ion beam. The various parameters include, for example, a voltage applied each of the condenser lens electrode 16 and the objective lens electrode 17 described above, etc. Further, the various parameters may include another parameter, instead of some or all of the parameters or in addition to some or all of the parameters. Further, the various parameters are tested in advance by the mask repair apparatus 100 to be determined so that the ion beam column 1 irradiates a desired position with the nitrogen ion beam.

Further, the device controller C1 reads first detection condition information stored in the storage R in advance from the storage R. The device controller C1 sets various detection conditions indicated by the read first detection condition information to the ion beam column 1. The first detection condition information indicates various detection conditions set to the ion beam column 1 when the mask repair apparatus 100 radiates the nitrogen ion beam. The various detection conditions include, for example, a contrast value, a bright value, etc. Further, the various detection conditions may include another condition, instead of some or all of the conditions or in addition to some or all of the conditions.

After the setting is performed, the device controller C1 starts S110 in accordance with a manipulation received from the user.

The device controller C1 moves a position of the defect of the target EUVL mask that is the sample 3 placed on the sample holder 7 to an irradiation area of the ion beam by moving the sample stage 8. The device controller C1 controls the ion beam column 1, scans and radiates the nitrogen ion beam from the ion beam column 1 to the target EUVL mask, and, detects the secondary electron 4 generated from the target EUVL mask by the secondary electron detector 5. The device controller C1 obtains the observation image of the image forming portion 9 with respect to the target EUVL mask from a scanning signal of the nitrogen ion beam and a detection signal of the secondary electron detector 5 (S110).

The device controller C1 displays the obtained observation image on the display portion D, and performs setting of a position to be repaired for setting the ion beam irradiation area in a defect portion of the target EUVL mask (S120). Accordingly, the mask repair apparatus 100 determines the irradiation position of the ion beam.

The device controller C1 performs first etching processing (S130). Hereinafter, S130 will be described.

In S130, the device controller C1 reads first irradiation amount information stored in the storage R in advance from the storage R. The device controller C1 sets the amount of irradiation indicated by the read first irradiation amount information to the ion beam column 1. The device controller C1 irradiates beam irradiation area set in S120 with the nitrogen ion beam, and performs etching processing for the third layer 30 on the ion beam irradiation area as the above-described first etching processing. The device controller C1 radiates the nitrogen ion beam of the amount of irradiation set to the ion beam column 1 to the third layer 30, and then finishes the first etching processing. As described above, a method of etching of the third layer 30 in the first etching processing is an example of a first etching method. Further, the amount of irradiation indicated by the first irradiation amount information may be realized by being tested in advance by the mask repair apparatus 100, and is determined so that only the third layer 30 is etched by the nitrogen ion beam to the utmost (so that the second layer 31 on the ion beam irradiation area is not etched by the nitrogen ion beam to the utmost).

After S130 is performed, the device controller C1 checks the ion beam irradiation area set in S120, and determines whether or not the etching of the third layer 30 by the first etching processing is finished (S140).

When the etching of the third layer 30 by the first etching processing is not finished (S140—NO), the device controller C1 transitions to S130 so as to perform the first etching processing again. Note that, when the first etching processing is performed again, the device controller C1 may receive a manipulation of the user to adjust the amount of radiation of the nitrogen ion beam in the first etching processing.

Meanwhile, when the etching of the third layer 30 by the first etching processing is finished (S140—YES), the device controller C1 changes the setting (S150).

The S150 will be described. In S150, the device controller C1 sets the above-described second extraction voltage to the ion beam column 1 as the extraction voltage applied between the emitter 22 and the extraction electrode 23.

Further, the device controller C1 reads second observation condition information stored in the storage R in advance from the storage R. The device controller C1 sets various observation conditions indicated by the read second observation condition information to the ion beam column 1. The second observation condition information indicates various observation conditions when the mask repair apparatus 100 radiates the hydrogen ion beam. The various observation conditions include the acceleration voltage for accelerating the hydrogen ion beam, a beam current of the hydrogen ion beam, the lens mode which is the operation mode of the objective lens focusing the hydrogen ion beam, the type of the sample holder 7 maintaining the sample 3, the material of the sample 3, the position of the sample stage 8 where the sample 3 is placed, etc. Further, the various observation conditions may include another condition, instead of some or all of the conditions or in addition to some or all of the conditions.

Further, the device controller C1 reads second lens parameter information stored in the storage R in advance from the storage R. The device controller C1 sets various parameters indicated by the read second lens parameter information to the ion beam column 1. The second lens parameter information indicates various parameters set to the ion beam column 1 when the mask repair apparatus 100 radiates the hydrogen ion beam. The various parameters include, for example, a voltage applied to each of the condenser lens electrode 16 and the objective lens electrode 17. Further, the various parameters may include another parameter instead of some or all of the various parameters or in addition to some or all of the various parameters. The various parameters are tested in advance by the mask repair apparatus 100 to be determined so that the ion beam column 1 radiates the hydrogen ion beam to a desired position. The desired position is the same as the position where the nitrogen ion beam is radiated. The nitrogen ion beam is an example of a heavy ion beam. Further, in the description, the heavy ion beam means an ion beam of an element that is heavier than hydrogen.

Further, the device controller C1 reads second detection condition information stored in the storage R in advance from the storage R. The device controller C1 sets various detection conditions indicated by the read second detection condition information to the ion beam column 1. The second detection condition information indicates various detection conditions set to the ion beam column 1 when the mask repair apparatus 100 radiates the hydrogen ion beam. The various detection conditions include, for example, the contrast value, the bright value, etc. Further, the various detection conditions may include another condition instead of some or all of the detection conditions or in addition to some or all of the detection conditions.

After S150 is performed, the device controller C1 starts second etching processing (S160). Hereinafter, the S160 will be described.

In S160, the device controller C1 reads second irradiation amount information stored in the storage R in advance from the storage R. The device controller C1 sets the amount of irradiation indicated by the read second irradiation amount information to the ion beam column 1. The device controller C1 supplies xenon fluoride from the gas supply 6 to the surface of the sample 3 as the etching gas, and irradiates the ion beam irradiation area with the hydrogen ion beam so as to perform the etching processing for the second layer 31 on the ion beam irradiation area as the above-described second etching processing. That is, the device controller C1 performs gas assist etching using xenon fluoride as the second etching processing. The device controller C1 irradiates the second layer 31 with the hydrogen ion beam of the amount of irradiation set to the ion beam column 1, and then finishes the second etching processing. As described above, a method of etching of the second layer 31 in the second etching processing (in the example, gas assist etching) is an example of a second etching method. Further, the amount of irradiation indicated by the second irradiation amount information is determined by being tested in advance by the mask repair apparatus 100.

In the second etching processing, it may be difficult to perform the etching of the third layer 30 on the ion beam irradiation area. For example, when a material of the third layer 30 is Al as the example, it is difficult to perform the etching of the third layer 30 in the gas assist etching using xenon fluoride as the etching gas. Therefore, in this case, the mask repair apparatus 100 performs the etching of the third layer 30 on the ion beam irradiation area by the first etching processing, and then perform the etching of the second layer 31 on the ion beam irradiation area by the second etching processing. Whereby, the mask repair apparatus 100 may efficiently repair the defect of the target EUVL mask.

After the S160 is performed, the device controller C1 checks the ion beam irradiation area set in S160 to determine whether or not the etching of the second layer 31 by the second etching processing is finished (S170).

When the etching of the second layer 31 by the second etching processing is not finished (S170—NO), the device controller C1 transitions to S160 so as to perform the second etching processing again. In the second etching processing, the first layer 32 is not etched. Therefore, when the second etching processing is performed again, the device controller C1 receives a manipulation from the user to adjust the amount of radiation of the hydrogen ion beam in the second etching processing, and may receive the manipulation and not to adjust the amount of irradiation.

Meanwhile, when the etching of the second layer 31 by the second etching processing is finished (S170—YES), the device controller C1 finishes the processing.

Further, the device controller C1 may be configured to oxidize a side surface (side wall) of a groove formed in the second layer 31 by the second etching processing by adding an oxidizing agent into the vacuum sample chamber 11, after the etching of the second layer 31 by the second etching processing is finished in S160, or during the etching of the second layer 31 by the second etching processing in S160. Further, the vacuum sample chamber 11 is an example of a space where a EUVL mask is disposed. The oxidizing agent may be any oxidizing agent.

As described above, in the first embodiment, the mask repair apparatus 100 performs the etching of the third layer 30 by the first etching processing, and after the etching of the third layer 30 by the first etching processing, the mask repair apparatus 100 performs the etching of the second layer 31 by the second etching processing different from the first etching processing. Accordingly, the mask repair apparatus 100 may efficiently repair the defect of the target EUVL mask.

In the first embodiment, as the first etching method, the etching of the third layer 30 is performed by the method for etching of the third layer 30 in the first etching processing, that is, the method for etching of the third layer 30 by using the nitrogen ion beam (example of heavy ion beam). Further, in the first embodiment, as the second etching method, the etching of the second layer 31 is performed by using the method for etching of the second layer 31 by using the gas assist etching using xenon fluoride. Accordingly, the mask repair apparatus 100 may efficiently repair the defect of the target EUVL mask by using two kinds of ion beams with different ionic species.

### <2^{nd} Embodiment>

Hereinafter, a second embodiment of the present disclosure will be described. In the second embodiment, the same reference numerals will be used to refer the parts same as the first embodiment, and detailed descriptions thereof will be omitted.

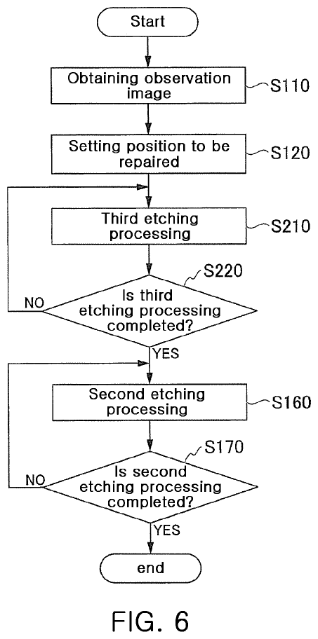

In the second embodiment, as the repair of the defect of the target EUVL mask, the mask repair apparatus 100 performs the processing illustrated in a flowchart in FIG. 6 instead of the processing illustrated in the flowchart in FIG. 5. FIG. 6 is a flowchart illustrating another example of processing for repairing the defect of the target EUVL mask by the mask repair apparatus 100. Processing from S110 to S120 illustrated in FIG. 6 is the same processing from S110 to S120 illustrated in FIG. 5, and descriptions thereof will be omitted. Also, processing from S160 to S170 illustrated in FIG. 6 is the same processing from S160 to S170 illustrated in FIG. 5, and descriptions thereof will be omitted.

The device controller C1 makes various settings at the timing before S110 illustrated in FIG. 6.

The device controller C1 sets the above-described second extraction voltage to the ion beam column 1 as the extraction voltage applied between the emitter 22 and the extraction electrode 23.

The device controller C1 reads the second observation condition information stored in the storage R in advance from the storage R. The device controller C1 sets the various observation conditions indicated by the read second observation condition information to the ion beam column 1.

The device controller C1 reads the second lens parameter information stored in the storage R in advance from the storage R. The device controller C1 sets the various parameters indicated by the read second lens parameter information to the ion beam column 1.

The device controller C1 reads the second detection condition information stored in the storage R in advance from the storage R. The device controller C1 sets the various detection conditions indicated by the second detection condition information to the ion beam column 1.

After the settings are performed, the device controller C1 starts S110 illustrated in FIG. 6 on the basis of a manipulation received from the user.

After S120 illustrated in FIG. 6 is performed, the device controller C1 performs third etching processing (S210). Hereinafter, the processing of S210 will be described.

In S210, the device controller C1 reads third irradiation amount information stored in the storage R in advance from the storage R. The device controller C1 sets the amount of irradiation indicated by the read third irradiation amount information to the ion beam column 1. The device controller C1 performs the etching processing for the third layer 30 on the ion beam irradiation area as the above-described third etching processing by supplying 1-2 diiodoethane from the gas supply 6 to the surface of the sample 3 as the etching gas, and irradiating the ion beam irradiation area with the hydrogen ion beam to. That is, the device controller C1 performs gas assist etching using 1-2 diiodoethane as the third etching processing. The device controller C1 irradiates the third layer 30 with the hydrogen ion beam of the amount of irradiation set to the ion beam column 1, and then finishes the third etching processing. In the third etching processing, the method for etching of the third layer 30 (in the example, gas assist etching) is an example of the first etching method. Further, 1-2 diiodoethane is an example of a gas of a first type. The amount of irradiation indicated by the third irradiation amount information is determined by being tested in advance by the mask repair apparatus 100.

After S210 is performed, the device controller C1 checks the ion beam irradiation area set in S210, and determines whether or not the etching of the third layer 30 by the third etching processing is finished (S220).

When the etching of the third layer 30 by the third etching processing is not finished (S220—NO), the device controller C1 transitions to S210 so as to perform the third etching processing again. In the third etching processing, the second layer 31 is not etched. Therefore, when the third etching processing is performed again, the device controller C1 receives the manipulation from the user to adjust the amount of radiation of the hydrogen ion beam in the third etching processing, and may be configured to receive the manipulation not to adjust the amount of irradiation.

Meanwhile, when the etching of the third layer 30 by the third etching processing is finished (S220—YES), the device controller C1 transits to S160 illustrated in FIG. 6. In the second etching processing performed in S160 illustrated in FIG. 6, the method for etching of the second layer 31 (in the example, gas assist etching using xenon fluoride as etching gas) is an example of the second etching method. Xenon fluoride is an example of a gas of a second type.

Further, the device controller C1 may be configured to oxidize the side surface (side wall) of the groove formed in the second layer 31 by the second etching processing by adding the oxidizing agent into the vacuum sample chamber 11, after the etching of the second layer 31 by the second etching processing in the processing of S160 in FIG. 6 or during the etching of the second layer 31 by the second etching processing in the processing of S160.

As described above, in the second embodiment, as the first etching method, the etching of the third layer 30 is performed by using the method for etching of the third layer 30 in the third etching processing, that is, the method for etching of the third layer 30 by the gas assist etching using 1-2 diiodoethane that is the example of the gas of the first type. Further, in the first embodiment, as the second etching method, the etching of the second layer 31 is performed by using the method for etching of the second layer 31 by gas assist etching using xenon fluoride that is the example of the gas of the second type. Accordingly, the mask repair apparatus 100 may efficiently repair the defect of the target EUVL mask by using a kind of ion beam.

As described above, the mask repair apparatus according to the embodiment, which repairs the defect of the target EUVL mask that is a EUVL mask including the reflective layer, the first layer disposed on the reflective layer, the second layer disposed on the first layer, and the third layer disposed on the second layer, performs the etching of the third layer by the first etching method, and after the etching of the first etching method is performed, performs the etching of the second layer by the second etching method different from the first etching method. Accordingly, the mask repair apparatus 100 may efficiently repair the defect of the target EUVL mask.

As described above, although preferred embodiments of the present disclosure has been described for illustrative purposes, those skilled in the art will appreciate that various modifications, additions and substitutions are possible, without departing from the scope and spirit of the invention as disclosed in the accompanying claims.

Further, the described apparatus (for example, the control device 10) may be configured such that a program for realizing a function of an optional component is stored in a computer-readable recording medium, and a computer system reads the program to execute the program. Further, “the computer system” used herein includes hardware such as an operating system (OS) or a peripheral device. “The computer-readable storage medium” is a portable medium such as a flexible disk, a magneto-optical disk, a ROM, and a compact disk (CD)-ROM, and a storage medium such as a hard disk provided in the computer system. “The computer-readable storage medium” includes a medium that is provided with a communication line such as a telephone line and a network such as the internet to maintain the program for a certain time like volatile memory (RAM) in the computer system that is server or client when the program is sent.

The program may be connected with a transmission medium from the computer system that stores the program in the storage medium, or may be transmitted to another computer system by a transmission wave in the transmission medium. “The transmission medium” transmitting the program is a medium having a function of transmitting information like the network (communication network) such as the internet or the communication line such as the telephone line.

The program may be provided to realize some of the functions described above. The program may be a difference file (difference program) capable of realizing the above-described functions in combination with a program stored in advance in the computer system.

What is claimed is:

1. A mask repair apparatus for repairing a defect of a target extreme ultra violet lithography (EUVL) mask comprising a reflective layer, a first layer disposed on the reflective layer, and a second layer disposed on the first layer, and a third layer disposed on the second layer, wherein the mask repair apparatus is configured to perform etching of the third layer by a first etching method and, after performing etching of the third layer by a first etching method, performing etching of the second layer by a second etching method that is different from the first etching method.

2. The mask repair apparatus of claim 1, wherein the first layer is a cap layer and the second layer is an absorption layer.

3. The mask repair apparatus of claim 1, wherein a material of the third layer is any one of aluminum, chromium, and ruthenium.

4. The mask repair apparatus of claim 1, wherein the first etching method is a method of performing etching of the third layer by a heavy ion beam and the second etching method is gas-assisted etching.

5. The mask repair apparatus of claim 1, wherein the first etching method is gas-assisted etching using a gas of a first type, and the second etching method is gas-assisted etching using a gas of a second type that is different from the gas of the first type.

6. The mask repair apparatus of claim 1, wherein, after etching of the second layer by the second etching method or during etching of the second layer by the second etching method, an oxidizing agent is added into a space in which the target EUVL mask is disposed.

7. A method for repairing a mask, wherein a target extreme ultra violet lithography (EUVL) mask is an EUVL mask comprising a reflective layer, a first layer disposed on the reflective layer, and a second layer disposed on the first layer, and a third layer disposed on the second layer, the method comprising:
a first step performing etching of the third layer by a first etching method; and
a second step performing, after performing the first step, performing etching of the second layer by a second etching method that is different from the first etching method.
